(19) United States
(12) Patent Application Publication
(10) Pub. No.: US 2011/0133231 A1
(43) Pub. Date: Jun. 9, 2011

(54) EXTENSIVE AREA LED HAVING ROUGNESS SURFACE

(75) Inventors: Pun Jae Choi, Gyeonggi-do (KR); Myeong Kook Gong, Gyeonggi-do (KR); Jin Soo Park, Gwangju (KR); Hyun Goo Kim, Chungcheongnam-do (KR); Bae Hwan Oh, Chungcheongnam-do (KR)

(73) Assignee: EPIPLUS CO., LTD., Gyeonggi-do (KR)

(21) Appl. No.: 11/791,035

(22) PCT Filed: Jan. 7, 2005
(86) PCT No.: PCT/KR2005/000037

§ 371 Date: Jul. 20, 2009

(30) Foreign Application Priority Data
Dec. 14, 2004 (KR) 10-2004-0105834

(51) Int. Cl. H01L 33/58

(52) U.S. Cl. 257/98; 257/E33.074

(57) ABSTRACT

The structure for fixing packing of a lid (1) of an airtight container comprises a ring shaped groove (5) formed at a lower surface of the lid (1), a packing (6) that includes a tight contacting surface part (10) upwardly expanded in an outward direction for sealing gaps based on a tight contact with an inner wall surface (9) of the container body (8), and a fixing surface part (7) that is horizontally extended in a direction of an inner side of the tight contacting surface part (10); a plurality of slits (12) that are formed at the fixing surface part (7) of the packing (6) at regular intervals in arc shapes each having the same width as the ring shaped groove (5); and a packing fixing member (13) that is protruded and has the same cross section shape as the slit of the packing (6).

### TECHNICAL FIELD

The present invention relates to an extensive area LED having a roughness surface, and more particular, to an extensive area LED with a non-reflection surface capable of increasing the amount of emitted light by etching a transparence electrode and a P-type region layer, or only the P-type region layer to form the non-reflection surface in order to minimize a loss of light.

### BACKGROUND ART

In recent, a display apparatus, which displays an information visually, is rapidly advanced along with the growth of IT(Information Technology) and mobile telecommunication technology. The display apparatus can be divided into a projection type, a direct vision type, a visual image-using type, and a hologram type according to a driving type. The direct vision type is divided into an active type display with a characteristic of emitting light by itself and a passive type with a characteristic of emitting light by foreign source.

The recent development trend turns towards a LCD(Liquid Crystal Display), a PDP(Plasma Display Pannel), and OELD(Organic Elector Luminescence Display), which substitute the existing display devices, in order to achieve high brightness, a high speed response characteristic, a high intensity, and the total number of processes.

In particular, the LED(Light Emitting Diode) with characteristics of small-sized, low power consumption and high reliability is widely used as a display means. The material for the LED is III-V compound semiconductor such as AlGaAs, GaAlP, GaP and InGaAlP, which use As and P as V-element and emit led light, orange color light, yellow light and green light. The material for the LED is also GaN based compound semiconductor, which emits green light, blue light and ultraviolet light. A high intensity LED is achieved through the compound semiconductor.

In conventional GaN based LED, when a current is applied to a LED through a lead frame, the applied current is expanded through a transparence electrode with a high conductivity and injected into N-type GaN layer and P-type GaN layer, respectively. And, an energy hν (h: Plank's constant, ν=c/λ, c: the velocity of light, λ; wavelength) generated at the PN junction is emitted out of the LED.

Further, an efficiency of light emitting in the LED is divided into an internal quantum efficiency, which depends on a design and quality of an active layer, and an external quantum efficiency, which depends on an amount of the light emitted out of the LED form the active layer. The external quantum efficiency further depends of a refractive index and a critical angle.

That is to say, in the external quantum efficiency, a GaN(Gallium nitride) based material or a sapphire with a constant refractive index should not exceed a critical angel in order to emit a generated light in the an air with the refractive index 1. As shown FIG. 1, GaN, and air or resin have a different refractive index, and thus have a different refractive angle. The critical angle for emitting light to air or resin is represented by θ_{c}=sin⁻¹(N₁/N₂). When light is advanced from GaN to air, the critical angle is about 24.6°.

If light having an angle above the critical angle is generated in a chip, the light is reflected back to the inside of the chip to be confined in the inside. Further, the light is absorbed between GaN and a sapphire as a substrate to reduce the external quantum efficiency.

In recent, as dimensions(500 μm ˜3 mm) of an extensive area light emitting diode for a TV monitor, a computer monitor, and a headlight is larger than that (250 μm ˜400 μm) of a light emitting diode which is used a back light for mobile phone, a light loss due to light-emitting through a side of chip is occurred in the extensive area light emitting to further reduce the external quantum efficiency.

FIG. 2 is a graph showing a loss of light emitted from a side of a chip according to the distance from the side. FIG. 3 is a graph showing an absorbance according to a variation of frequency in GaN-based compound. FIG. 4 is a view showing arrangement of an electrode and an active area of a prior art extensive area LED.

Referring figures, as the light loss is about 90% at a distance of 200 μm from the side of the chip, light is hardly emitted from the side when a distance exceeds 200 μm.

in particular, GaN based compound is generally used for a green and a blue LED. When the blue and an ultraviolet LED are used, an absorbance of light is greatly increased. Therefore, decrement of light emitted from the side of chip is severe.

Thus, as the size of the prior art extensive area LED is generally within 500 μm˜3 mm, a light, which is generated from an active layer and reflected within LED, is not emitted to the outside, but absorbed by absorption to reduce an external quantum efficiency.

### DISCLOSURE OF THE INVENTION

Therefore, an object of the present invention is to solve the problems involved in the prior art, and to provide an extensive area light emitting diode in which a roughness area is formed by etching a transparence electrode and a P-type region, or P-type region in order to emit a light reflected and moved with an angle over a critical angle in the diode, and a roughness area is formed on a scribing area of the extensive area diode or the outside of N-type electrode to emit a light, which is generated in an active layer, with maximal to increase an external quantum efficiency.

### BRIEF DESCRIPTION OF THE DRAWINGS

The above objects, other features and advantages of the present invention will become more apparent by describing the preferred embodiment thereof with reference to the accompanying drawings, in which:

FIG. 1 is a view illustrating a critical angle for emitting of light in Gallium nitride layer,

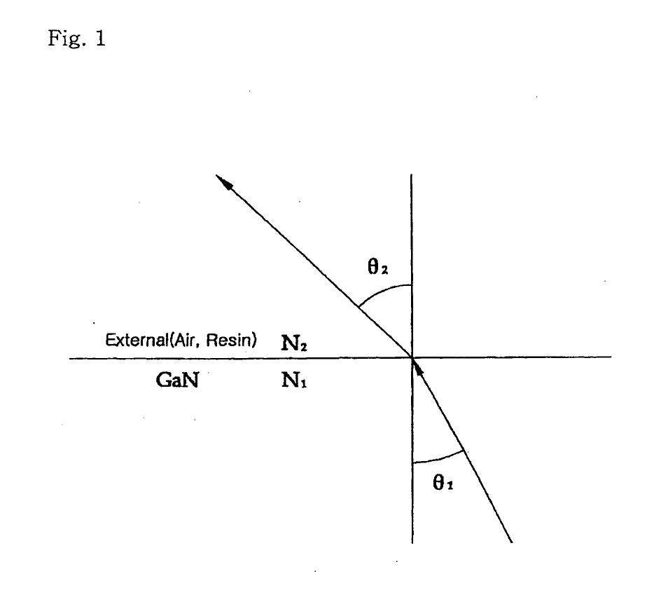

FIG. 2 is a graph showing a loss of light emitted from a side of a chip according to the distance from the side,

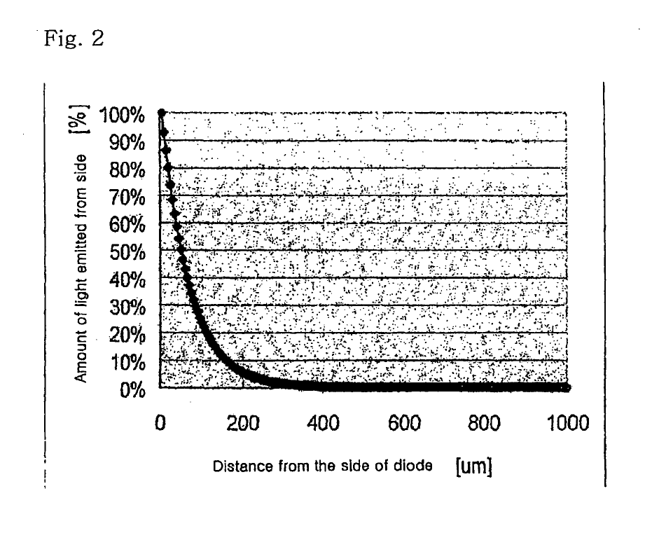

FIG. 3 is a graph showing an absorbance according to a variation of frequency in GaN-based compound,

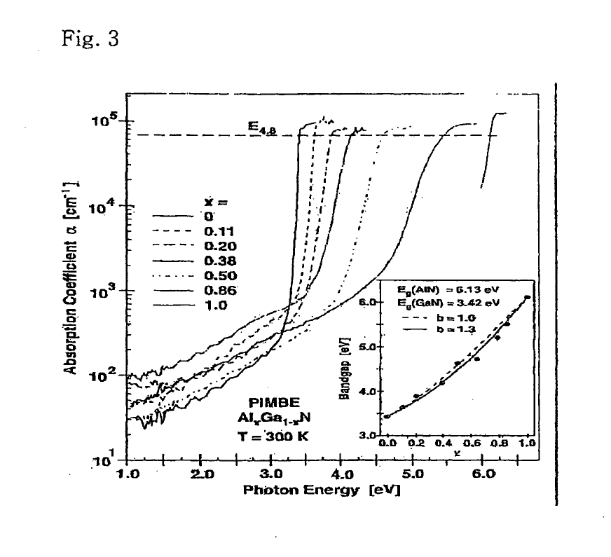

FIG. 4 is a view showing arrangement of an electrode and an active area of a prior art extensive area LED.

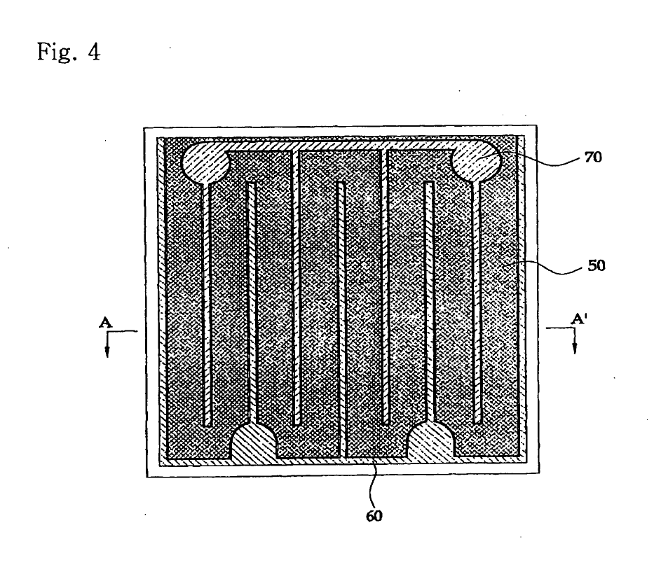

FIG. 5 is a cross-sectional view taken along line A-A′ in FIG. 4,

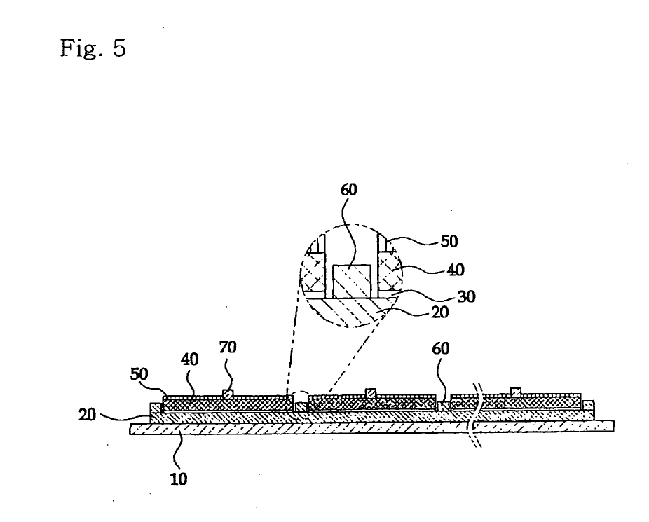

FIG. 6 is a view showing arrangement of an electrode and an active area of an extensive area LED according to one embodiment of the present invention,

FIG. 7 is a cross-sectional view taken along line B-B′ in FIG. 6,

FIG. 8 is a cross-sectional view taken along line C-C′ in FIG. 6,

FIG. 9 is a view showing arrangement of an electrode and an active area of an extensive area LED according to other embodiment of the present invention,

FIG. 10 is a view showing arrangement of an electrode and an active area of an extensive area LED according to another embodiment of the present invention,

### BRIEF DESCRIPTION OF REFERENCE NUMBER

| | |
|---|---|
| 10: substrate | 20: N-type layer |
| 30: active layer | 40: P-type layer |
| 50: transparence electrode | 60: N-type electrode |
| 70: P-type electrode | 80: roughness area |

### BEST MODE FOR CARRYING OUT THE INVENTION

According to the present invention, an extensive area light emitting diode, which comprises a substrate, a N-type layer on the substrate, an active layer for emitting light, a P-type layer, a transparence electrode on the N- and P-type layers, is characterized by forming a roughness area by etching the transparence electrode and the P-type layer, or the P-type layer to minimize a loss of light.

In addition, in the present invention, the roughness area is formed on the outside of the N-type electrode, or a scribing area of the extensive area diode by etching the transparence electrode and the P-type layer, or the P-type layer.

Reference will now be made in detail to an anti-reflected high efficiency light emitting diode device according to the present invention by using the accompanying drawings. In the following explanation, a description through accompanying drawings will be added in order to facilitate further complete understanding of the present invention, but it is apparent to those skilled in the art that the present invention can be carried out without a detailed description of the drawings. In cases, a description of the main elements or constituents of the known technology will be omitted if it obscures the point of the present invention unnecessarily. This is intended to avoid any possibility to obscure the description of the present invention.

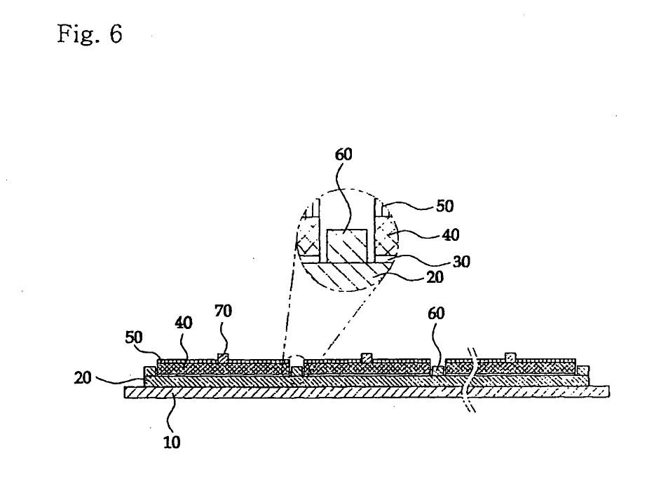

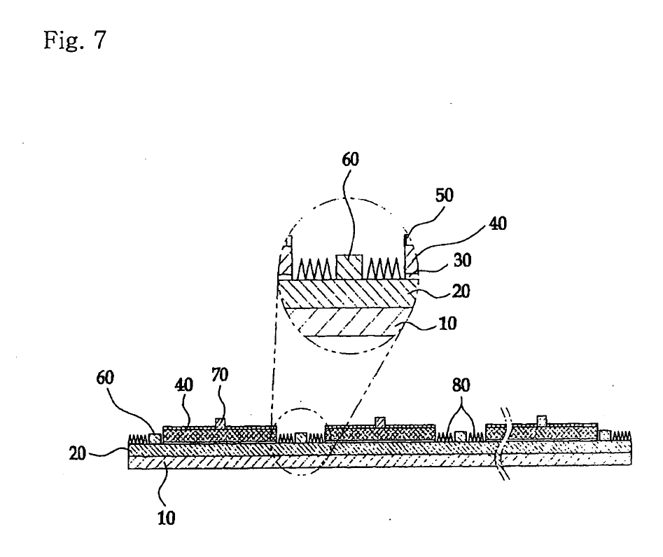

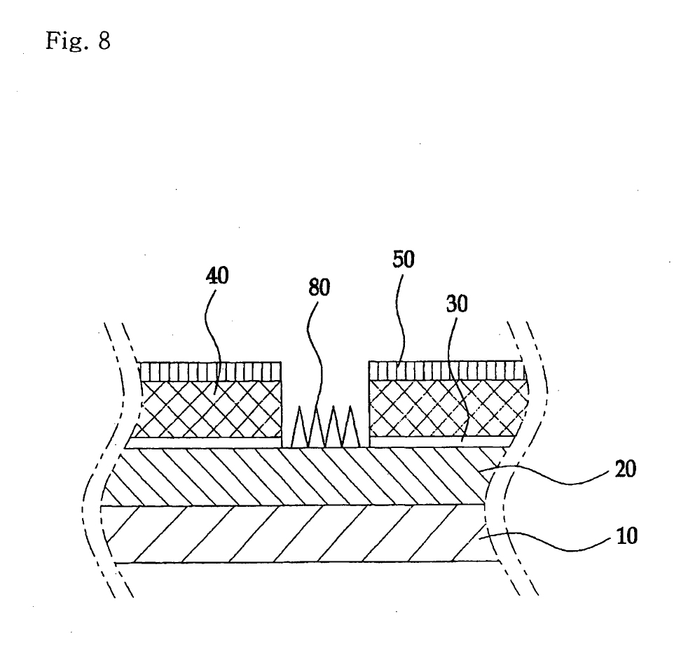

FIG. 6 is a view showing arrangement of an electrode and an active area of an extensive area LED according to one embodiment of the present invention, FIG. 7 is a cross-sectional view taken along line B-B′ in FIG. 6, and FIG. 8 is a cross-sectional view taken along line C-C′ in FIG. 6.

Referring to figures, a N-type layer 20, an active layer 30 for emitting light, a P-type layer 40 and a transparence electrode 50 are formed on a substrate 10 in sequence in the extensive area light emitting diode. Electrodes 70 and 80 are alternately formed on the N-type layer 20 and the P-type layer 40, respectively, for applying an electronic power.

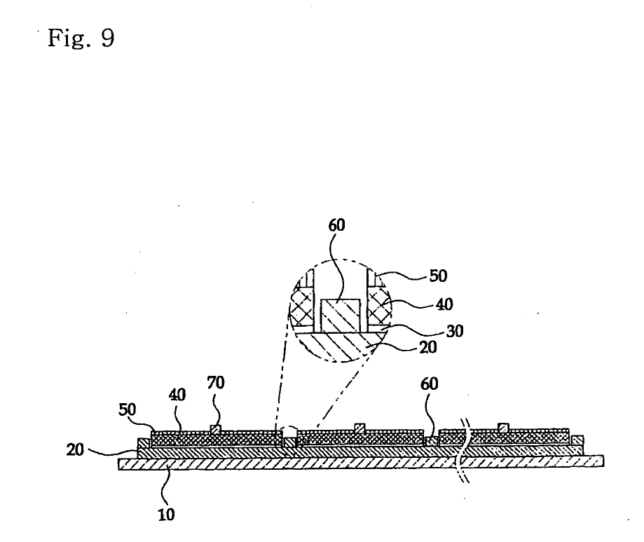

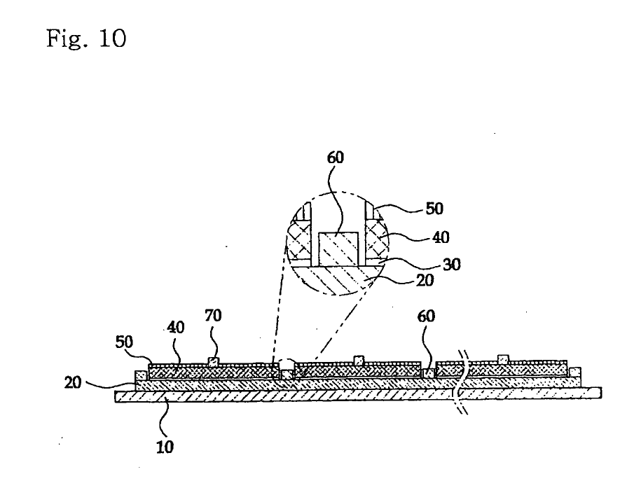

The arrangement of the electrodes 70 and 80, and an active region is various as shown in FIGS. 6, 9 and 10. A roughness area for emitting in maximal a light, which has an angle over a critical angle and is reflected in the inside of the diode, is formed on a proper position irrespective of the arrangement of the electrodes and the active region.

The term ‘active region’ used in here means a region excepting the electrodes 60 and 70, which emits a light in the extensive area light emitting diode. The roughness area(or surface) 80 is formed by etching the active region.

As shown in FIG. 6, the roughness area 80 is formed on the exposed N-type layer 20, which is exposed by etching the P-type layer 40 between the N-type electrode 60 and the P-type electrode 70. The roughness area 80 means an area, which has a prominence and depression equal to the wavelength of light emitted from the diode to pass most of the light according Fresnel's law irrespective of an incident angle.

The light, which has an angle over the critical angle and is reflected in the inside of diode, is easily emitted at the roughness area 80 to increase an efficiency of light emitting.

In order to the roughness area 80, a metal is deposited onto the N-type layer 20, which is exposed by etching the P-type layer 40, to be heat-treated in high temperature. Then, a metal cluster is formed, and an ultra-fine prominence and depression structure is formed on the metal cluster.

Further, the roughness area can be formed by depositing a roughness metal on the P-type layer 40, and by a physical and mechanical treatment. According to processes, the roughness area can be formed by depositing a roughness metal on the transparence electrode 50.

The roughness area 80 can be formed on the P-type layer 40, the active layer 30 or the N-type layer 20 according to the rate of etching.

Further, the roughness area 80 is formed on one position along width-direction, or numbers of positions spaced apart between the N-type electrode 60 and the P-type electrode 70.

The N-type electrode 60 is branched off in the roughness area 80, and other roughness area 80 can be formed around the branched off electrodes.

As described above, the electrodes 60 and 70 can be arranged with various according to power save and an effective flow of current. The roughness area 80 can be formed on the outside of the N-type electrode 60, or on the active region in order to maximize the light emitting.

Numbers of roughness areas are formed in figures, and 90% of light is lost when the distant is over 200 μm as described above, the distance between an area and an adjacent area is desirably 100 μm˜300 μm to minimize the loss of light and to maximize the size of the active region.

Further, when comparing the size of the roughness area 80 to the total size of the active region, if the size of the roughness area 80 is relatively small, the light is not emitted outside and is reflected and absorbed in the inside. If the size of the roughness 80 is relatively big, the size of the active region is accordingly reduced, and the amount of light emitted outside is reduced.

Therefore, the ratio of the roughness area 80 to the total active region is about 10%.

The roughness area 80 is formed by etching the P-type layer 40 around the N-type electrode 60 between the P-type layers 40 separated by the N-type electrode 60.

Further, in process of fabricating the extensive area light emitting diode, the roughness area 80 is formed on a scribing region of the diode, which is needed for cleavage.

According to the embodiments of the present invention, the light, which is generated at the active layer 30 and has an angle over a critical angle, is reflected to the inside of diode, and if the light is reached to the roughness area 80, or the roughness area 80 around the N-type electrode 60, the light is not reflected and emitted to outside to increase the efficiency of the light emitting.

While the present invention has been described and illustrated herein with reference to the preferred embodiments thereof, it will be apparent to those skilled in the art that various modifications and variations can be made therein without departing from the spirit and scope of the invention. Thus, it is intended that the present invention covers the modifications and variations of this invention that come within the scope of the appended claims and their equivalents.

### INDUSTRIAL APPLICABILITY

According to one aspect of the present invention, the efficiency of the light emitting is increased to rise the external quantum efficiency by optimizing the arrangement of the roughness area, and guiding the light over the critical angle to the roughness area.

When the roughness areas according to the present invention are spaced apart with 200 μm˜300 μm, the external quantum efficiency is increased by 15%-20% comparing with the conventional efficiency 7.2%. Thus, the total efficiency is about 8.6%-9.0%

1. An extensive area light emitting diode having roughness surface including a substrate 10, a N-type layer 20, an active layer 30 for emitting light, and a P-type layer 40, a transparence electrode 50, and electrodes 70 and 80 positioned on the N-type layer 20 and the P-type layer 30 respectively, the extensive area light emitting diode comprising:
a roughness area 80 is formed by etching the transparence electrode 50 and the P-type layer 40, or the P-type layer 40 to minimize a loss of light.

2. The extensive area light emitting diode having roughness surface as claimed in claim 1, wherein the roughness area 80 formed around the N-type electrode.

3. The extensive area light emitting diode having roughness surface claimed in claims 1, wherein the roughness area 80 is formed on a scribing region of the diode.

4. The extensive area light emitting diode having roughness surface as claimed in claims 1, wherein the electrodes 60 and 70 are alternately positioned on the N-type layer 20 and the P-type layer 40, and the roughness area 80 is formed on one position or numbers of positions between the N-type electrode 60 and the P-type electrode 70.

5. The extensive area light emitting diode having roughness surface as claimed in claim 4, wherein The roughness area 80 is formed around the N-type electrode 60 between the P-type layers 40 separated by the N-type electrode 60.
